(19) United States
(12) Patent Application Publication
(10) Pub. No.: US 2003/0128781 A1
(43) Pub. Date: Jul. 10, 2003

(54) Means and method for precursor ISI cancellation

(76) Inventors: Tho Le-Ngoc, AnJou (CA); Francois Trans, Los Altos, CA (US)

Correspondence Address: FENWICK & WEST LLP, SILICON VALLEY CENTER, 801 CALIFORNIA STREET, MOUNTAIN VIEW, CA, 94041, US

(21) Appl. No.: 10/341,872

(22) Filed: Jan. 13, 2003

Related U.S. Application Data
(63) Continuation of application No. 09/444,007, filed on Nov. 19, 1999.
Application No. 09/444,007 is a continuation-in-part of application No. 09/417,528, filed on Oct. 13, 1999.
(60) Provisional application No. 60/104,316, filed on Oct. 13, 1998.

(51) Int. Cl. H04L 1/00; H03D 1/06; H04B 1/10

(52) U.S. Cl. 375/348; 375/350

(57) ABSTRACT

The DPIC makes use of the D detected symbols from the output of the Slicer to estimate the precursor ISI which still exists at the input sample of the Slicer. The estimation of the residual ISI value is done by a D-tap Finite Impulse Filter (FIR). This D-tap FIR has the same structure as the DFE or the Echo or NEXT canceller except the values of the coefficients. Since it calculates, A D-symbol delay element is used to keep the DT-delayed sample, from which the corresponding residual precursor ISI computed the D-tap FIR, is removed.

### BACKGROUND OF THE INVENTION

The Gigabit 1000BaseT (802.3ab) is based on synchronous transmission to facilitate the cancellation of ECHO/NEXT/FEXT Interference at the receiver. To achieve synchronous transmission between two PHYs at the ends of a link, a master-slave clocking relationship is established by the PHYs. The master-slave relationship between two stations sharing a link-segment is established during the auto-negotiation. The master-PHY (Repeater/Hub/Switches) uses an external clock (such as Com2000™ Clock) to determine the timing of transmitter and receiver operations. This master clock is also provided to the other stations in the network. The slave-PHY (Network NIC or Edge node) recovers the clock from the received signal and uses it to determine the timing of transmitter operations.

The Master-Slave relationship essentially establishes a 1000BaseT connection as a closed-loop system that spans the link segment. This is similar to the arrangement found in 100BaseT2, ISDN, HDSL, and other applications, but this is different from that found in 100BaseTx, 100Base-T4 and 10BaseT. In a master-slave arrangement, the slave PHY (Edge node) has to perform its receiver functions correctly in order for the master to establish a proper operation of its receiver. In contrast, in 100BaseTx, for example, each PHY can independently establish a proper receiver operation.

Problem:

Gigabit and Multi-Gigabit transmission of digital data over CAT5 cables requires adaptive equalization to equalize channel distortion and adaptive interference cancellation to remove both echo and crosstalk interference (NEXT's and FEXT's).

Channel distortion includes mainly amplitude distortion and delay dispersion. It causes the smearing and elongation of the duration of each symbol. In network communications where the data symbols closely follow each other, specially at multiple of gigabit speed, time dispersion results in an overlap of successive symbols, an effect known as inter-symbol interference (ISI). Equalization system in concert with a synchronous communication environment alleviates the relative phase dispersion of the interfered and interfering signals that greatly reduces ISI. This is a critical factor affecting the CAT5 receiver performance.

Interference (echo and crosstalk) is another major performance-limiting impairments on UTP cables.

In many systems, perfect equalization and interference cancellation are not possible and residual ISI, NEXT's and FEXT's are present at the decision device (slicer).

To deliver a robust Multi-Gigabit data stream over CAT5 cable in the Ethernet embodiment of this system, the sources of interference and noise for a 1000/2000 Base-T system need to be analyzed in order to provide methods of removing interference and increasing the Signal to Noise Ratio (SNR).

The problem is that there may be insufficient margin in SNR for the receiver to operate reliably (at the required threshold BER on an existing CAT5 cable plant. The Gigabit 1000BaseT (802.3ab) 3 dB Receiver Design and analysis found that there is only a small SNR margin (1.8 dB) for CAT5 Cable TIA TSB-67 category 5 Specifications if the NEXT's are ignored. In presence of NEXT's, the margin can be negative which is not enough of a margin.

### SUMMARY OF THE INVENTION

This disclosure describes the implementation details and performance of the means and method of interference suppression for wireline communications, called Decision Precursor ISI Canceller (DPIC). The DPIC uses the D detected symbols from the output of the Slicer to estimate the precursor ISI which still exists at the input sample of the Slicer. The estimation of the residual ISI value is done by a D-tap Finite Impulse Filter (FIR). This D-tap FIR has the same structure as the DFE or the Echo or NEXT canceller except the values of the coefficients. Since it calculates, A D-symbol delay element is used to keep the DT-delayed sample, from which the corresponding residual precursor ISI computed by the D-tap FIR, is removed. For the purposes of this description, the invention will be described with reference to the 1000BaseT/802.3ab standard.

Organization:

In Section II, we describe the channel characteristics and modeling used to evaluate the performance of various receiver structures. In Section III, we present the receiver structures currently proposed for the transmission of Gigabit Ethernet over 4 cat-5 UTP cables and their limited performance. Section IV describes the introduced DPIC techniques and its applications in the design of various receiver structures using both Echo and NEXT cancellers. Their performance and complexity as compared to the existing schemes are discussed. A significant performance improvement offered by the introduced DPIC techniques is shown. In Section V, we present the applications of the introduced DPIC techniques to the design of new receiver structures without NEXT cancellers. The new structures offer improvement in both performance and complexity.

### CHANNEL CHARACTERISTICS AND MODELING

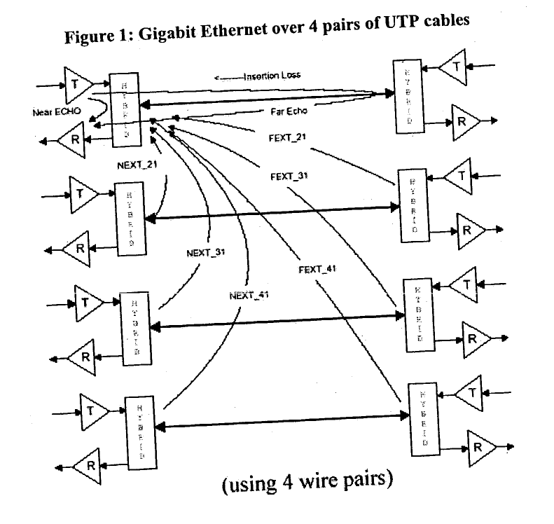

The two major causes of performance degradation for transceivers operating over UTP wiring are propagation loss and crosstalk generated between pairs, as shown in FIG. 1 [6].

As shown in FIG. 1, each UTP support a 250 Mb/s full-duplex channel using a 5-level 125 Mbaud transmission scheme. Consider the transmission on pair#1. With respect to the Receiver #1L on the left, its wanted signal is sent by the Transmitter #1R on the right. The transmitter #1L on the left sends a signal to the Receiver #1R on the right, but also generates spurious signal (called echo) to its own Receiver#1L on the left. The interference signals generated by Transmitters 2L-4L on the left appear at the input of the Receiver #1L are called near-end crosstalk (NEXT) interferers, NEXT_21 to NEXT_41. The interference signals generated by Transmitters 2R-4R on the right appear at the input of the Receiver #1L are called far-end crosstalk (FEXT) interferers, FEXT_21 to FEXT_41.

Propagation Loss:

The models for the propagation loss of a loop that are presented in this section are valid for frequencies that are larger than about 500 kHz. The signals considered in this paper have a very small amount of energy below this frequency. Thus, for simplicity, we will assume that the propagation loss models discussed here are valid at all frequencies.

The transfer function H(d, f) of a perfectly terminated loop with length d can be written as follows:

H(d,f)=e^{-dγ(f)}=e^{-dα(f)}e^{-jdβ(f)} (1)

where γ(f) is the propagation constant, α(f) is the attenuation constant, and β(f) is the phase constant. The quantity that is usually specified in practice is the propagation loss for a given cable length (e.g., d=100 meters). The propagation loss (or insertion loss) limit L_{P}(f) for category 5(cat-5) 100 m cable is a positive quantity expressed in dB

$$\begin{matrix}{L}_{P} ( f ) = - 20 log \vert H ( 1 , f ) \vert \\ = \frac{20}{ln 10} α ( f ) \approx 8.686 ( a \sqrt{f} + bf )\end{matrix}$$

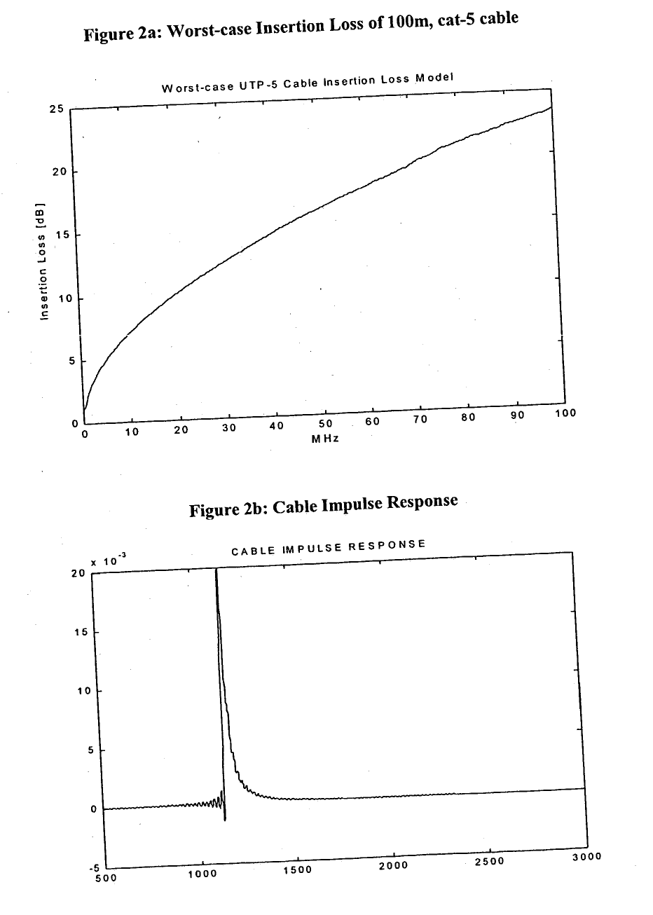

The plot of the propagation loss limit for cat-5, 100 m cable and the cable impulse response are shown in FIGS. 2a and b, respectively.

ECHO Loss:

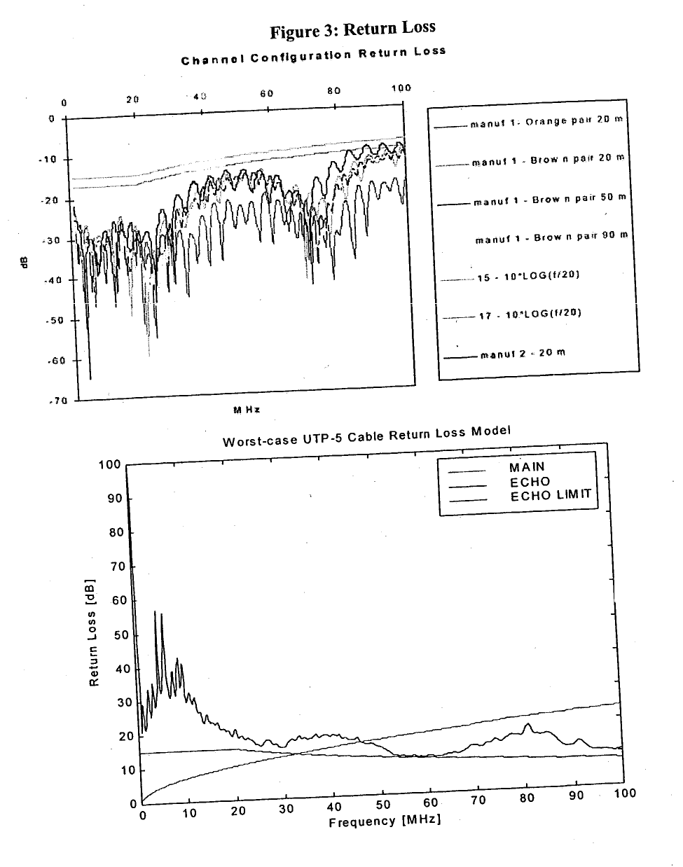

The Echo loss is indicated by the return loss. FIG. 3 shows the plot of the measured return loss and the return loss limit which is 15 dB for frequency from 1 to 20 MHz and 15-10 log(f/20) for frequency from 20 to 100 MHz.

NEXT Loss:

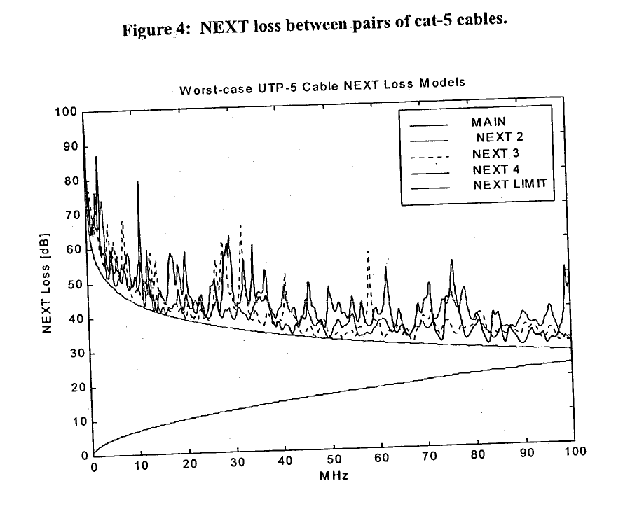

The wavy curves in FIG. 4 give the measured pair-to-pair NEXT loss characteristics for three different combinations of twisted pairs in 100 m cat-5 cables. The existence of the minima (small loss) and maxima (large loss) in these curves is due to the fact that the frequencies considered here correspond to wavelengths that are in the same length range as the distance between points of unbalance in the NEXT coupling path. Notice that the minima and maxima usually occur at different frequencies for the three pair combinations. Notice also that the NEXT loss corresponding to the minima decreases with increasing frequency and tends to follow the smooth dotted curve on the bottom in the figure, which is defined as the worst-case pair-to-pair NEXT loss (or NEXT loss limit) as a function of frequency. The worst-case TIA/EIA-568-A NEXT loss model shown in FIG. 4 is 27.1-16.8 log(f/100) in dB.

FEXT Loss:

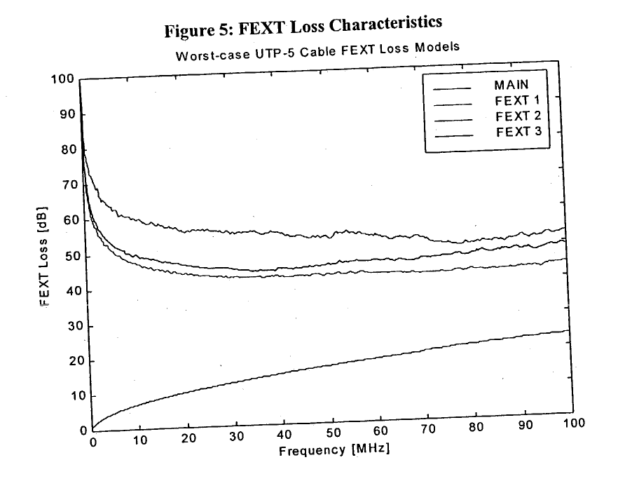

FIG. 5 shows the FEXT loss curves.

Channel Modeling:

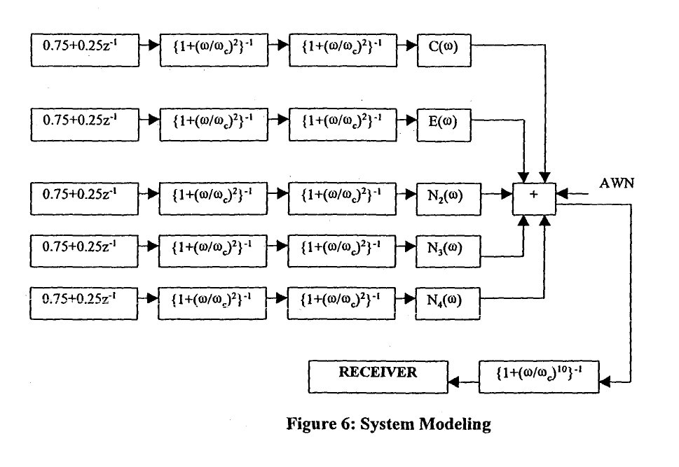

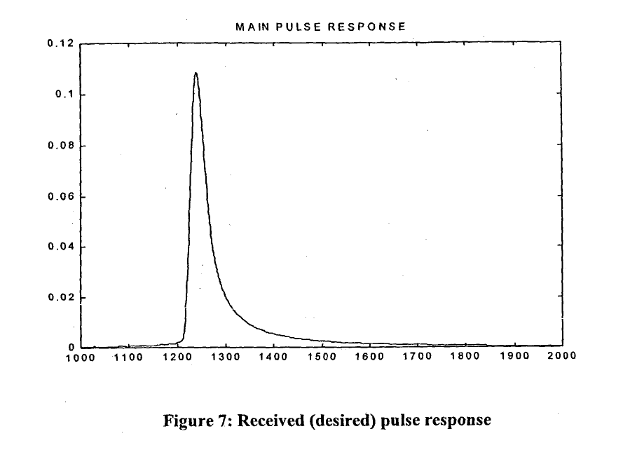

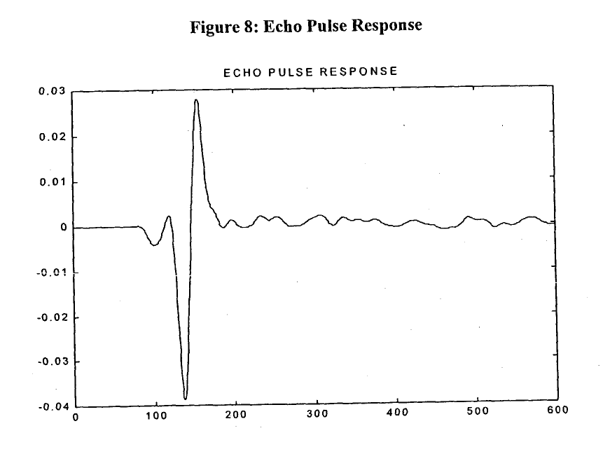

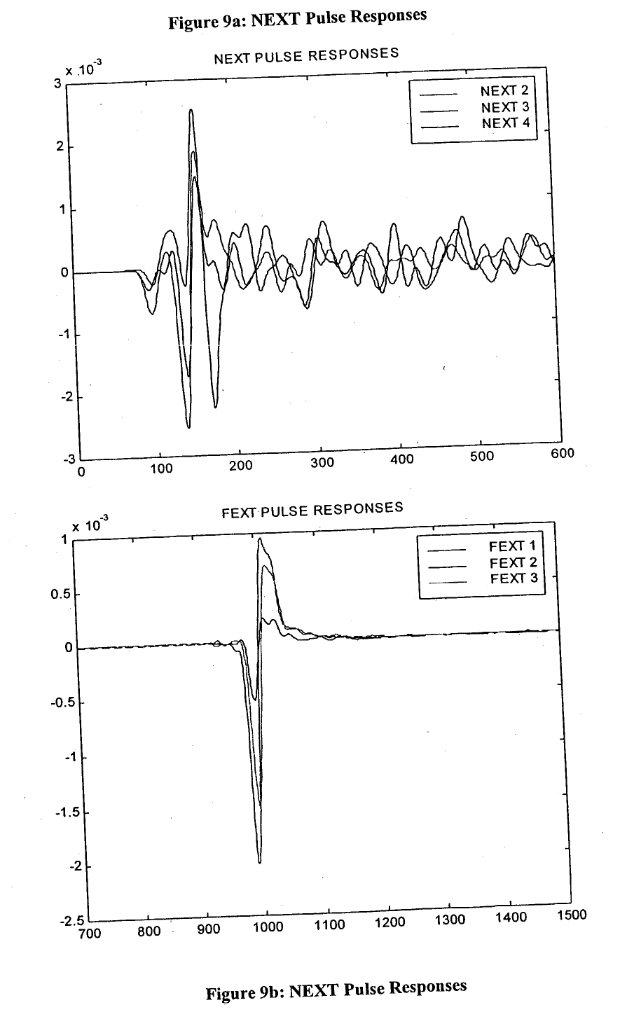

FIG. 6 shows the channel model including the effects of partial response, DAC and hybrid filtering in the transmitter, the main and coupling channel characteristics, and the filtering in the receiver front-end. The DAC and hybrid filtering is represented by the cascade of two identical first-order Butterworth sections with a corner frequency of 180 MHz. This introduces a 4 ns rise/fall time. The receiver front-end is modelled as a fifth-order Butterworth filter with a corner frequency of 80 MHz. The main channel, echo coupling and NEXT coupling channels are represented by C(ω), E(ω), N₂(ω), N₃(ω), and N₄(ω), respectively. The models for the FEXT's are similar to those of the NEXT's except the coupling channels will be F₂(ω), F₃(ω), and F₄(ω), instead of N₂(ω), N₃(ω), and N₄(ω). The pulse responses of the main, echo, NEXT's and FEXT's at the input of the RECEIVER shown in FIG. 6 are shown in FIGS. 7, 8, and 9, respectively.

### TRADITIONAL INTERFERENCE CANCELLATION AND EQUALIZATION TECHNIQUES AND THEIR LIMITED PERFORMANCE

Reliable duplex operation at 250 Mb/s over two pairs of a CAT-5 UTP cable requires the usage of some kind of technique to remove inter-symbol interference (ISI) and to combat interference including echo, NEXT and FEXT. Since the FEXT has a smaller contribution in interference level, and FEXT source data are not available at the receiver side, we neglect FEXT's and focus on the echo and NEXT's.

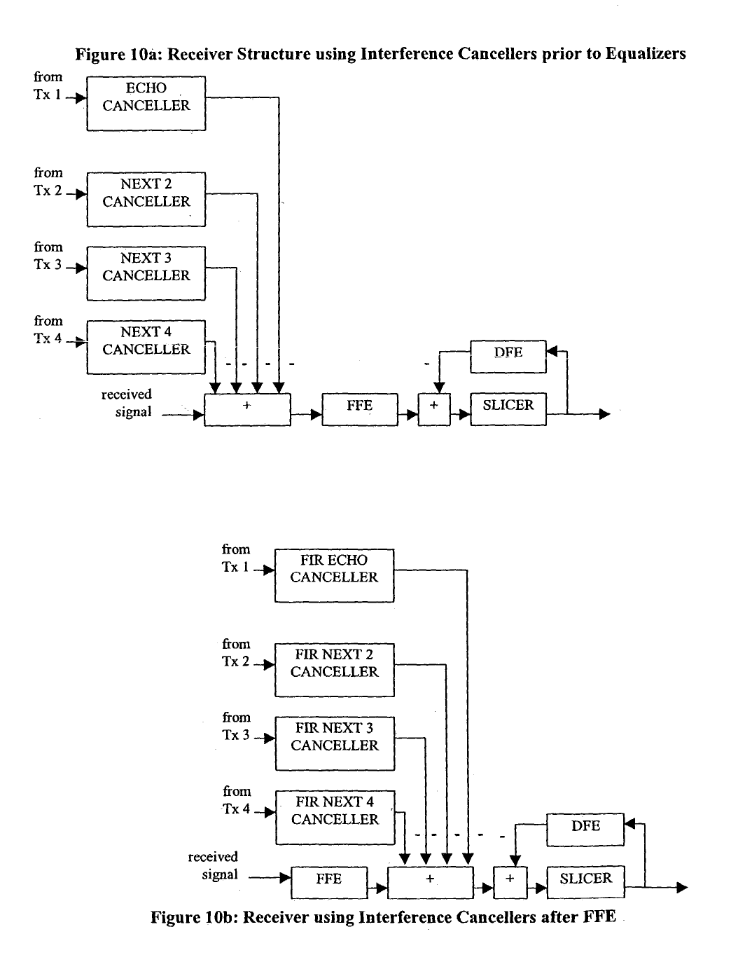

Traditional structures are shown in FIGS. 10a and b. A NEXT canceller synthesizes, in an adaptive fashion, a replica of the NEXT interferer. The interferer is then cancelled out by subtracting the output of the canceller from the signal appearing at the receiver. A NEXT canceller has the same principle of operation as an echo canceller, and all the familiar structures used for echo cancellers can also be used for NEXT cancellers. The cancellers need to have access to the local transmitters from which they get their input signals. Typically, this input signal is the stream of symbols generated by the transmitter's encoder. In FIG. 10a the output signal of the canceller is subtracted from the received signal immediately after the A/D. With such an approach, the canceller has to generate outputs at the same rate as the sampling rate of the A/D. An alternative is to make the subtraction at the input of the slicer as shown in FIG. 10b. In this case, the outputs of the canceller need only be generated at the symbol rate.

The FFE (feed-forward equalizer) in FIGS. 10a and b can be a symbol-spaced (SS) or fractionally spaced (FS) FFE or an analog equalizer. It is used to equalize the precursor ISI. The DFE is used to remove the post cursor ISI. Note that the performance of the DFE is also dependent on the reliability of the symbols detected by the slicer and influenced by the error propagation. For this, one may replace the simple slicer by a sequence detector (such as Viterbi decoder) for a better performance. In that case, the long processing delay of the decoder can be an issue.

In [6], the structure shown in FIG. 10b is adopted for the section of the receiver prior to the 4D-TCM Viterbi decoder. It consists of 4 paths and each path includes:

one M-tap Symbol-Spaced (SS) Feedforward Equalizer (FFE) to remove the precursor ISI,

one N-tap Decision Feedback Equalizer (DFE) to remove the post-cursor ISI,

one E-tap Echo Canceller to eliminate the echo interference, and

three X-tap NEXT Cancellers to eliminate the NEXT interferers.

Including the coding gain of 6 dB from the 4D-TCM Viterbi Decoder, calculations have been made to achieve 3 dB and 10 dB margins and a target output SNR of 16.2 dB for a BER=1E-10. For convenience, we will call the corresponding 3 dB-margin and 10 dB-margin designs Scheme PL (Proposed structure with Low complexity) and Scheme PH (Proposed structure with High complexity), respectively. Their structures and numbers of taps are:

SCHEME PL: ONE 50-TAP ECHO CANCELLER, THREE 12-TAP NEXT CANCELLERS, SYMBOL-SPACED 12-TAP FFE, AND 10-TAP DFE (and ADC with effective 48 levels).

SCHEME PH: ONE 121-TAP ECHO CANCELLER, THREE 72-TAP NEXT CANCELLERS, SYMBOL-SPACED 16-TAP FFE, AND 12-TAP DFE (and ADC with effective 96 levels).

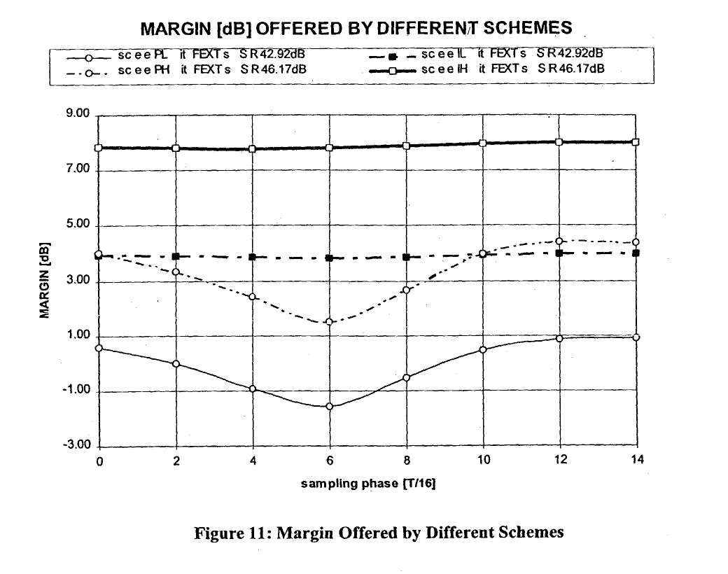

Note that study was done with the assumption that the FEXT's are neglected. The margin was expected to be adequate for FEXT's. Therefore, in the presence of 3 FEXT's, the margins provided by Schemes PL and PH are reduced. It is noted that Scheme PL has a much lower complexity than Scheme PH (a total saving of 71 echo canceller taps, 180 NEXT taps, 4 FFE taps and 2 DFE taps per path). FIG. 11 shows the plots of the margin including 6 dB-coding gain when FEXT's are present. It indicates that Scheme PL is not acceptable due to the insufficient margin (i.e., shown as negative margin) while the margin of Scheme PH varies between 1.5 dB to 4.5 dB dependent on the sampling phase. This can be marginal in practice.

### DECISION PRECURSOR ISI CANCELLATION TECHNIQUE

An investigation of the contribution of interferers shows the following distribution of equivalent RMS voltages of the interference at the receiver input: 104 mV for ISI, 35.5 mV for Echo, 4.5 mV for total NEXT and 3.1 mV for total FEXT. It indicates a large value of ISI. The Symbol-Spaced Feedforward Equalizer is supposed to remove the precursor ISI. However, it works with samples (not detected symbols) and samples contain noise (predominantly quantization noise). Therefore, the Symbol-Spaced Feedforward Equalizer is not so effective in removing the precursor ISI. In other words, there is a substantial level of residual precursor ISI at the input to the Slicer and it reduces the output SNR.

To improve further the output SNR we propose the new decision precursor ISI cancellation technique.

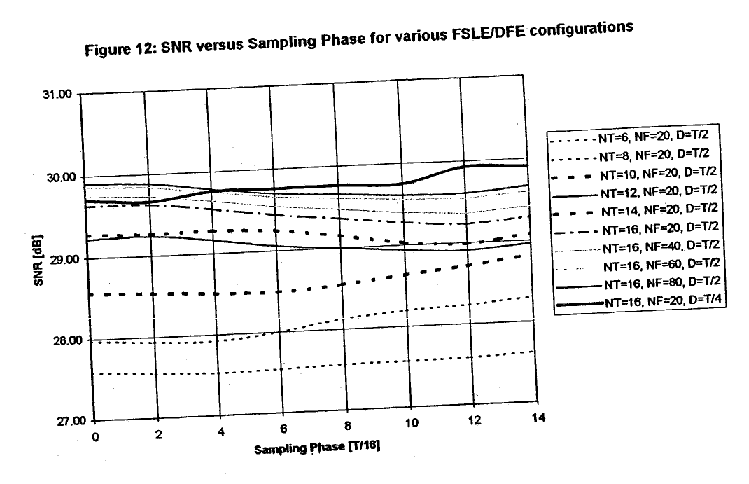

FIG. 12 shows the position of the invented Decision Precursor ISI Canceller (DPIC). The DPIC makes use of the D detected symbols from the output of the Slicer to estimate the precursor ISI which still exists at the input sample of the Slicer. The estimation of the residual ISI value is done by a D-tap Finite Impulse Filter (FIR). This D-tap FIR has the same structure as the DFE or the Echo or NEXT canceller except the values of the coefficients. Since it calculates, A D-symbol delay element is used to keep the DT-delayed sample, from which the corresponding residual precursor ISI computed by the D-tap FIR is removed. The DPIC has a simple structure with D-symbol delay (or a memory of D locations) and a D-tap FIR. The value of D is small. We consider a DPIC with D=10 or 12 in the following schemes:

SCHEME IL: ONE 50-TAP ECHO CANCELLER, THREE 12-TAP NEXT CANCELLERS, SYMBOL-SPACED 12-TAP FFE, 10-TAP DFE (and ADC with effective 48 levels) and ONE 10-TAP DECISION PRECURSOR ISI CANCELLER. (i.e., SCHEME PL with DPIC)

SCHEME IH: ONE 121-TAP ECHO CANCELLER, THREE 72-TAP NEXT CANCELLERS, SYMBOL-SPACED 16-TAP FFE, 12-TAP DFE (and ADC with effective 96 levels), and ONE 12-TAP DECISION PRECURSOR ISI CANCELLER. (i.e., SCHEME PH with DPIC)

It can be seen that Schemes IL and IH are actually the improved versions of Schemes PL one 10-tap DPIC and PH with one 12-tap DPIC, respectively. FIG. 2 shows the performance of Schemes IL and IH as compared to Schemes PL and PH. We observe from FIG. 2 the following:

The performance of both new Schemes IL and IH is robust, insensitive to the sampling phase.

Both new Schemes IL and IH provide positive margins.

The new Scheme IL provides a margin of 4 dB while the currently proposed Scheme PH has a worse performance than new Scheme IL except for the timing phases of 10T/16 to 15T/16 where Scheme PH is better by at most 0.5 dB. Note that the complexity of currently proposed Scheme PH is much higher than that new Scheme IL as shown in Table 1 (3 times).

The new Scheme IH provides a large margin of 8 dB (including 6 dB from the 4D-TCM Viterbi Decoder) or a performance improvement of 4 dB over the currently proposed design. This implies that without 4D-TCM and complex Viterbi Decoder, the new Scheme IH still provide 2 dB margin. In other words,

the 4D-TCM and complex Viterbi Decoder can be dropped for cost and simplicity, or

the new DPIC technique can be used in conjunction with 4D-TCM and complex Viterbi Decoder for high performance and longer distance, or higher capacity.

TABLE 1
Complexity of PL, PH, IL, and IH

| | currently | | currently | | new, | | new, | |
|---|---|---|---|---|---|---|---|---|
| | proposed | | proposed | | improved | | improved | |
| | Scheme PL | | Scheme PH | | Scheme IL | | Scheme IH | |
| Echo Canceller | 50 | taps | 121 | taps | 50 | taps | 121 | taps |
| (using symbols): | | | | | | | | |
| NEXT Cancellers | 3 × 12 | taps | 3 × 72 | taps | 3 × 12 | taps | 3 × 72 | taps |
| (using symbols): | | | | | | | | |
| FFE (using samples): | 12 | taps | 16 | taps | 12 | taps | 16 | taps |
| DFE (using symbols): | 10 | taps | 12 | taps | 10 | taps | 12 | taps |
| DPIC (using symbols): | | | | | 10 | taps | 12 | taps |
| Delay element: | | | | | 10 | locations | 12 | locations |
| Total no. of taps | 96 | taps | 349 | taps | 106 | taps | 361 | taps |
| using symbols: | | | | | | | | |
| Total no. of taps | 12 | taps | 16 | taps | 12 | taps | 16 | taps |
| using samples: | | | | | | | | |
| TOTAL NO. OF TAPS: | 106 | taps | 361 | taps | 116 | taps | 371 | taps |

### DPIC-FFE-DFE-EC SCHEMES WITHOUT NEXT CANCELLERS

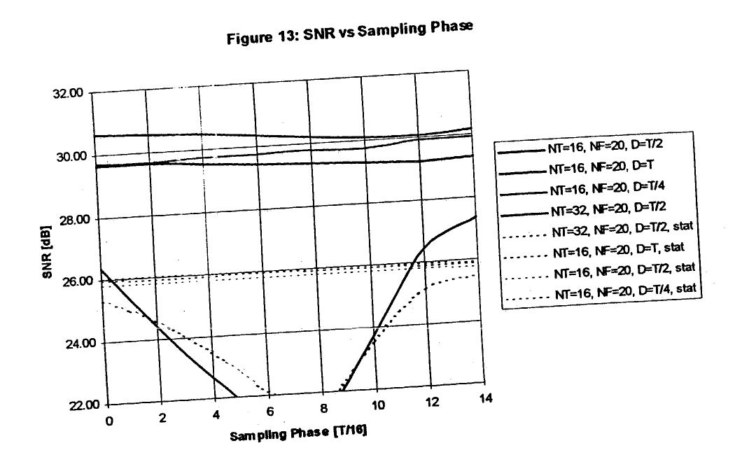

DPIC can be used with Fractionally Spaced or Symbol Spaced feedforward equalizer (FS-FFE or SS-FFE) plus DFE plus Echo Canceller to obtain an excellent performance without NEXT Cancellers (hence simpler structure) as shown in FIG. 13.

Three more schemes are considered, ILE(T), IHE(T) and IHE(T/2) using the structure shown in FIG. 13 above. ILE(T) and IHE(T) use a Symbol-Spaced FFE while IHE(T/2) use a Fractionally Spaced T/2-FFE. The numbers of taps and complexity of these schemes for the Gigabit receiver are summarized in Table 2.

TABLE 2
Complexity of various schemes

| | CURRENTLY | | | | OUR SCHEMES WITH | | | | OUR SCHEMES WITHOUT | | | | | |
|---|---|---|---|---|---|---|---|---|---|---|---|---|---|---|
| | PROPOSED | | | | NEXT CANCELLERS | | | | NEXT CANCELLERS | | | | | |
| | PL | | PH | | IL | | IH | | ILE(T) | | IHE(T) | | IHE(T/2) | |
| Echo Cancel- | 50 | taps | 121 | taps | 50 | taps | 121 | taps | 50 | taps | 121 | taps | 121 | taps |
| ler (using | | | | | | | | | | | | | | |
| symbols): | | | | | | | | | | | | | | |
| NEXT Cancel- | 3 × 12 | taps | 3 × 72 | taps | 3 × 12 | taps | 3 × 72 | taps | | | | | | |
| lers (using | | | | | | | | | | | | | | |
| symbols): | | | | | | | | | | | | | | |
| FFE (using | 12 | taps | 16 | taps | 12 | taps | 16 | taps | 12 | taps | 16 | taps | 32 | taps |
| samples): | | | | | | | | | | | | | | |
| DFE (using | 10 | taps | 12 | taps | 10 | taps | 12 | taps | 10 | taps | 12 | taps | 12 | taps |
| symbols): | | | | | | | | | | | | | | |
| DPIC (using | | | | | 10 | taps | 12 | taps | 10 | taps | 12 | taps | 12 | taps |
| symbols:) | | | | | | | | | | | | | | |
| Delay element: | | | | | 10 | locations | 12 | location | 10 | locations | 12 | locations | 12 | locations |
| Total no. of | 96 | taps | 349 | taps | 106 | taps | 361 | taps | 70 | taps | 145 | taps | 145 | taps |
| taps using | | | | | | | | | | | | | | |
| symbols: | | | | | | | | | | | | | | |
| Total no. of | 12 | taps | 16 | taps | 12 | taps | 16 | taps | 12 | taps | 16 | taps | 32 | taps |
| taps using | | | | | | | | | | | | | | |
| samples: | | | | | | | | | | | | | | |

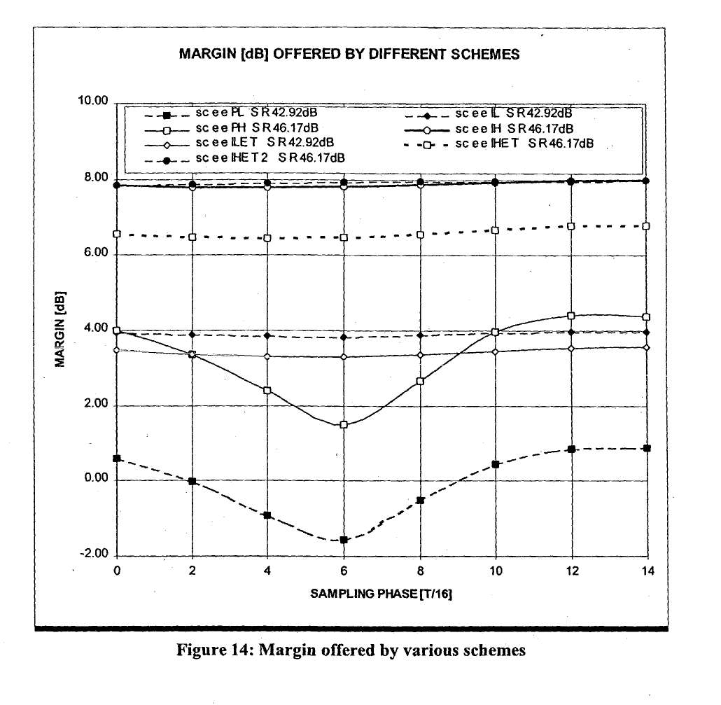

The performance in terms of margin (including the 6 dB from the Viterbi decoder is shown below (plotted in FIG. 14):

| | MARGIN [dB] | | | | | | |
|---|---|---|---|---|---|---|---|
| | PL | IL | PH | IH | ILE(T) | IHE(T) | IHE(T/2) |
| 0 | 0.59 | 3.94 | 4.00 | 7.83 | 3.47 | 6.56 | 7.84 |
| 2 | −0.03 | 3.89 | 3.35 | 7.80 | 3.37 | 6.49 | 7.88 |
| 4 | −0.93 | 3.84 | 2.40 | 7.78 | 3.31 | 6.45 | 7.91 |
| 6 | −1.55 | 3.83 | 1.49 | 7.80 | 3.30 | 6.48 | 7.93 |
| 8 | −0.53 | 3.87 | 2.66 | 7.87 | 3.35 | 6.55 | 7.95 |
| 10 | 0.45 | 3.93 | 3.99 | 7.94 | 3.45 | 6.67 | 7.96 |
| 12 | 0.86 | 3.97 | 4.40 | 7.99 | 3.54 | 6.78 | 7.97 |
| 14 | 0.89 | 3.97 | 4.38 | 7.99 | 3.55 | 6.81 | 7.98 |

FIG. 14 indicates the best performance with a margin (including Viterbi decoder) of 8 dB offered by our introduced schemes IH and IHE(T/2). From Table 2, Scheme IHE(T/2) only needs 145 “symbol” taps and 32 “sample” taps. The number of “symbol” taps is about 1.4 times larger than that of Scheme IL and still less than 0.5 that of the currently proposed scheme PH. Scheme IHE(T/2) needs a 32-tap T/2-spaced FFE operating at twice the symbol rate. Compared to IHE(T/2), the performance of IHE(T) is about 1 dB worse. However, Scheme IHE(T) uses a 16-tap Symbol-Spaced FFE operating at the symbol rate as the currently proposed PH. Scheme IHE(T) provides a significant improvement in both performance and complexity as compared to the existing scheme PH (i.e., “10 dB margin” design): 2.4 dB better in performance and 42% of the complexity.

For a much simpler structure, one can use Scheme ILE(T). From Table 2, Scheme ILE(T) only needs 70 “symbol” taps and 12 “sample” taps while Scheme PH (i.e., the existing “10 dB-margin design”) requires 349 “symbol” taps and 16 “sample” taps. In other words, the complexity of the introduced scheme ILE(T) is only 20% that of Scheme PH. This is a very substantial improvement in cost and complexity. From FIG. 14, it provides a solid margin of 3.5 dB. If the sampling phase is not properly selected, Scheme PH (existing “10 dB-margin design”) can has a poorer performance. For the best selected sampling phase, Scheme PH only provide 0.83 dB better than Scheme ILE(T) in performance.

We claim:

1. A method for canceling precursor Inter-Symbol Interference, the method comprising the steps of:
sampling the signal using a slice to generate an input sample;
estimating the precursor ISI which exists at the input sample of the slicer;
estimating a residual ISI value;
calculating a D-symbol delay element;
computing the corresponding residual precursor ISI using the calculated D-symbol delay element; and
removing the computed residual precursor ISI from the signal.

2. The method of claim 1, wherein the step of estimating the precursor ISI includes using detected symbols from the output of the Slicer

3. The method of claim 1, wherein the step for estimating is performed by using by a D-tap Finite Impulse Filter (FIR)

4. The method of claim 3, wherein the D-tap FIR used for estimating has the same structure as a DFE canceller.

5. The method of claim 3, wherein the D-tap FIR used for estimating has the same structure as an Echo canceller.

6. The method of claim 3, wherein the D-tap FIR used for estimating has the same structure as a NEXT canceller.

7. A system for canceling precursor Inter-Symbol Interference, the system comprising:
a 50-TAP ECHO canceller;
Coupled to the 50-tap canceller, three 12-TAP NEXT cancellers;
Coupled to the 12-TAP NEXT cancellers; a symbol-spaced 12-TAP FFE;
Coupled to the symbol spaced 12-TAP FFE, a 10-TAP DFE; and
Coupled to the 10-TAP DFE, a 10-TAP DECISION PRECURSOR ISI CANCELLER.

8. The system of claim 7, wherein the 12-TAP DFE further comprises an ADC with effective 96 levels.

9. A system for canceling precursor Inter-Symbol Interference, the system comprising:
a 121-TAP ECHO canceller;
Coupled to the 121-tap canceller, three 72-TAP NEXT cancellers;
Coupled to the 72-TAP NEXT cancellers; a symbol-spaced 16-TAP FFE;
Coupled to the symbol spaced 16-TAP FFE, a 12-TAP DFE; and
Coupled to the 12-TAP DFE, a 12-TAP DECISION PRECURSOR ISI CANCELLER.

10. The system of claim 9, wherein the 12-TAP DFE further comprises an ADC with effective 96 levels.
